(19) United States
(12) Patent Application Publication
(10) Pub. No.: US 2019/0086801 A1
(43) Pub. Date: Mar. 21, 2019

(54) PHOTOSENSITIVE RESIN COMPOSITION, TRANSFER FILM, MANUFACTURING METHOD OF PATTERN, DECORATIVE PATTERN, AND TOUCH PANEL

(71) Applicant: FUJIFILM Corporation, Tokyo (JP)

(72) Inventors: Soji ISHIZAKA, Shizuoka (JP); Shinichi KANNA, Shizuoka (JP); Kazumasa MOROZUMI, Shizuoka (JP); Takashi ARIDOMI, Shizuoka (JP)

(73) Assignee: FUJIFILM Corporation, Tokyo (JP)

(21) Appl. No.: 16/197,481

(22) Filed: Nov. 21, 2018

Related U.S. Application Data
(63) Continuation of application No. PCT/JP2017/019739, filed on May 26, 2017.

(30) Foreign Application Priority Data
May 31, 2016 (JP) 2016-109185

(51) Int. Cl. G03F 7/033; G06F 3/044; G03F 7/004; C08F 2/44

(52) U.S. Cl. CPC G03F 7/033; C08F 2/44; G03F 7/0047; G06F 3/044

(57) ABSTRACT

Provided are a photosensitive resin composition including: a binder having an I/O value equal to or greater than 0.5 and a weight-average molecular weight equal to or smaller than 25,000; a pigment; a polymerizable monomer; and a polymerization initiator, in which a content of the pigment is equal to or greater than 20% by mass with respect to a total amount of solid contents of the photosensitive resin composition, a transfer film including a photosensitive resin layer including the solid contents of the photosensitive resin composition, a manufacturing method of a pattern using the photosensitive resin composition or the transfer film, a decorative pattern using the photosensitive resin composition or the transfer film, and a touch panel including the decorative pattern.

### CROSS-REFERENCE TO RELATED APPLICATION

This application is a Continuation of International Application No. PCT/JP2017/019739, filed May 26, 2017, which claims priority to Japanese Patent Application No. 2016-109185 filed May 31, 2016. Each of the above applications is hereby expressly incorporated by reference, in its entirety, into the present application.

### BACKGROUND OF THE INVENTION

### 1. Field of the Invention

The present disclosure relates to a photosensitive resin composition, a transfer film, a manufacturing method of a pattern, a decorative pattern, and a touch panel.

### 2. Description of the Related Art

In the related art, a photosensitive resin composition including a binder (also referred to as a “binder polymer”, a “polymer”, or a “resin”) and a polymerizable monomer (also simply referred to as a “monomer”) has been known.

For example, a photosensitive resin composition which is used for forming a partition wall for ink jet for forming a colored region by applying a colored liquid composition including an organic solvent by an ink jet method, and includes at least a coloring material, a binder polymer, a monomer, and a polymerization initiator, in which I/O value of the binder polymer is equal to or greater than 0.58, and I/O value (b)×(M/B)≥0.49 (numerical expression (1)) [I/O value (b): I/O value of the binder polymer, M: mass of the monomer in the photosensitive resin layer, B: mass of the binder polymer in the photosensitive resin layer] is satisfied, has been known (for example, see JP2009-134263A).

In addition, a photosensitive composition including metal particles or particles including metal, an alkali soluble resin which is a copolymer having a specific repeating unit of 30% to 90% by mass, an acid value equal to or greater than 50 mgKOH/g, and an I/O value of 0.45 to 0.65, an additive polymerizable monomer including an ethylenically unsaturated double bond, and a photopolymerization initiator has been known (for example, see JP2007-256683A), as a photosensitive composition having a high concentration as a black sensitive material and having excellent dispersion stability of metal particles or particles including metal in a coating solution, pattern formability of such black matrix or the like (alkali developability and pattern shape), a surface state of the obtained pattern, solvent resistance of the obtained pattern, and formability of a thin film.

### SUMMARY OF THE INVENTION

From the studies of the inventors, it was determined that, developability is deteriorated, in a case of using a developer which is a carbonate aqueous solution (for example, a sodium carbonate aqueous solution), instead of a developer of the related art (for example, a triethanolamine type developer, a tetramethylammonium hydroxide developer, or the like), in a case of forming a pattern by performing pattern exposure and development of a photosensitive resin layer including solid contents of a photosensitive resin composition disclosed in JP2009-134263A and JP2007-256683A.

A concept of a deterioration of developability here includes at least one of the inability to perform development, an increase in a period of development time, or occurrence of development residue.

The developer which is the carbonate aqueous solution is used according to various purposes.

For example, a decorative pattern included in a touch panel or the like can be formed by performing pattern exposure and development of a photosensitive resin layer including solid contents of a photosensitive resin composition, and the developer which is the carbonate aqueous solution may be used as the developer at the time of this development.

A concept of “decorative” of the decorative pattern here also includes concealing of wirings disposed on a touch panel.

One embodiment of the invention provides a photosensitive resin composition having excellent developability even in a case of using a developer which is a carbonate aqueous solution, a transfer film including a photosensitive resin layer including solid contents of the photosensitive resin composition, a manufacturing method of a pattern using the photosensitive resin composition or the transfer film, a decorative pattern using the photosensitive resin composition or the transfer film, and a touch panel including the decorative pattern.

One embodiment of the invention includes the following aspects.
<1> A photosensitive resin composition comprising: a binder having an I/O value equal to or greater than 0.5 and a weight-average molecular weight equal to or smaller than 25,000; a pigment; a polymerizable monomer; and a polymerization initiator, in which a content of the pigment is equal to or greater than 20% by mass with respect to a total amount of solid contents of the photosensitive resin composition.
<2> The photosensitive resin composition according to <1>, in which the pigment is a black pigment.
<3> The photosensitive resin composition according to <1> or <2>, in which the polymerizable monomer includes a difunctional monomer.
<4> The photosensitive resin composition according to <3>, in which a content of the difunctional monomer is equal to or greater than 50% by mass with respect to a total amount of the polymerizable monomer.
<5> The photosensitive resin composition according to any one of <1> to <4>, in which a content of the polymerization initiator is greater than 0% by mass and smaller than 4% by mass with respect to a total amount of solid contents of the photosensitive resin composition.
<6> The photosensitive resin composition according to any one of <1> to <5>, in which a ratio of a total content mass of the polymerizable monomer with respect to a total content mass of the binder is 0.32 to 0.38.
<7> The photosensitive resin composition according to any one of <1> to <6>, in which an acid value of the binder having an I/O value equal to or greater than 0.5 and a weight-average molecular weight equal to or smaller than 25,000 is equal to or greater than 70 mg/KOH.
<8> The photosensitive resin composition according to any one of <1> to <7>, in which a content of the binder having an I/O value equal to or greater than 0.5 and a weight-average molecular weight equal to or smaller than 25,000 is equal to or greater than 5% by mass with respect to a total amount of solid contents of the photosensitive resin composition.
<9> The photosensitive resin composition according to any one of <1> to <8>, in which a content of the binder having an I/O value equal to or greater than 0.5 and a weight-average molecular weight equal to or smaller than 25,000 is equal to or greater than 50% by mass with respect to a total content of the binder included in the photosensitive resin composition.
<10> The photosensitive resin composition according to any one of <1> to <9>, which is used for forming a decorative pattern of a touch panel including the decorative pattern.
<11> A transfer film comprising: a temporary support; and a photosensitive resin layer including solid contents of the photosensitive resin composition according to any one of <1> to <10>.
<12> The transfer film according to <11>, further comprising: a functional layer disposed between the temporary support and the photosensitive resin layer.
<13> The transfer film according to <11> or <12>, which is used for forming a decorative pattern of a touch panel including the decorative pattern.
<14> A manufacturing method of a pattern comprising: a step of forming a photosensitive resin layer onto a base material using the photosensitive resin composition according to any one of <1> to <10> or the transfer film according to any one of <11> to <13>; a step of performing pattern exposure of the photosensitive resin layer formed on the base material; and a step of forming a pattern by developing the pattern-exposed photosensitive resin layer with a developer which is a carbonate aqueous solution.
<15> The manufacturing method of a pattern according to <14>, further comprising: a step of baking the pattern at a baking temperature equal to or lower than 200° C.
<16> A decorative pattern which is a patterned cured material of the photosensitive resin layer including solid contents of the photosensitive resin composition according to any one of <1> to <10> or the photosensitive resin layer of the transfer film according to any one of <11> to <13>.
<17> A touch panel comprising: the decorative pattern according to <16>.

According to one embodiment of the invention, a photosensitive resin composition having excellent developability, even in a case of using a developer which is a carbonate aqueous solution, a transfer film including a photosensitive resin layer including solid contents of the photosensitive resin composition, a manufacturing method of a pattern using the photosensitive resin composition or the transfer film, a decorative pattern using the photosensitive resin composition or the transfer film, and a touch panel including the decorative pattern are provided.

### BRIEF DESCRIPTION OF THE DRAWINGS

FIG. 1 is a schematic cross sectional view showing an example of a configuration of a transfer film of one embodiment.

FIG. 2 is a schematic plan view showing an example of a touch panel of the embodiment.

FIG. 3 is a schematic cross sectional view of a fine line pattern and a base material of the example and a schematic cross sectional view for describing a taper angle of a cross section of the fine line pattern.

### DESCRIPTION OF THE PREFERRED EMBODIMENTS

Hereinafter, one embodiment of the invention (hereinafter, also referred to as the “embodiment”) will be described.

In this specification, a range of numerical values shown using “to” means a range including numerical values before and after “to” as a lower limit value and an upper limit value.

In this specification, in a case where a plurality of substances corresponding to components are present in the composition, the amount of each component in the composition means a total amount of the plurality of substances present in the composition, unless otherwise noted.

In this specification, a term “step” not only includes an independent step, but also includes a step, in a case where the step may not be distinguished from the other step, as long as the expected object of the step is achieved.

In this specification, “(meth)acrylic acid” has a concept including both acrylic acid and a methacrylic acid, “(meth)acrylate” has a concept including both acrylate and methacrylate, and “(meth)acryloyl group” has a concept including both acryloyl group and methacryloyl group.

In this specification, a “total amount of solid contents” means a total mass of components other than a solvent.

In this specification, a “solid content of the photosensitive resin composition” means components other than the solvent in the photosensitive resin composition.

[Photosensitive Resin Composition]

A photosensitive resin composition of the embodiment includes a binder having an I/O value equal to or greater than 0.5 and a weight-average molecular weight (hereinafter, also referred to as “Mw”) equal to or smaller than 25,000; a pigment; a polymerizable monomer; and a polymerization initiator, in which a content of the pigment is equal to or greater than 20% by mass with respect to a total amount of solid contents of the photosensitive resin composition.

It was determined that, developability is deteriorated (for example, development may not be performed, a period of development time increases, although the development can be performed, or development residue occurs), in a case of using a developer which is a carbonate aqueous solution (for example, a sodium carbonate aqueous solution) having weak alkalinity (for example, pH of 9.0 to 12.0), instead of a developer of the related art (for example, a triethanolamine type developer, a tetramethylammonium hydroxide developer, or the like), in a case of forming a pattern by performing pattern exposure and development of a photosensitive resin layer including a photosensitive resin composition of the related art (for example, photosensitive resin composition disclosed in JP2009-134263A and JP2007-256683A) including a binder, a pigment, a polymerizable monomer, and a polymerization initiator. This tendency particularly significant occurs, in a case where the content of the pigment is equal to or greater than 20% by mass with respect to a total amount of solid contents of the photosensitive resin composition.

Regarding this point, according to the photosensitive resin composition of the embodiment, developability is excellent, even in a case of using a developer which is a carbonate aqueous solution.

Here, excellent developability means that the development can be performed, an increase in period of development time is prevented, and the occurrence of development residue is prevented (the same applies hereinafter).

It is thought that the effect of the developability is an effect caused by the binder (hereinafter, also referred to as a “specific binder”) having an 110 value equal to or greater than 0.5 and a weight-average molecular weight (Mw) equal to or smaller than 25,000, included in the photosensitive resin composition of the embodiment.

According to the photosensitive resin composition of the embodiment, by setting the Mw of the specific binder to be equal to or smaller than 25,000, a cross section shape of a pattern after baking can be set as an excellent cross section shape (that is, a tapered shape or a rectangular shape which will be described later), even in a case of baking the pattern obtained in the development at a temperature (for example, equal to or lower than 200° C.) lower than the temperature of the related art (for example, 240° C.).

It is thought that the reason for exhibiting such an effect is due to promotion of a deformation of a pattern edge (hereinafter, also referred to as “heat sagging”) due to heat of baking, by setting the Mw of the specific binder to be equal to or smaller than 25,000.

Hereinafter, an assumed mechanism for improving the cross section shape of the pattern after the baking using the heat sagging will be described.

However, the embodiment is not limited to the following assumed mechanism.

In general, in a case of performing the exposure and development of the photosensitive resin layer including a photosensitive resin composition (so-called negative photosensitive resin composition) including a binder, a polymerizable monomer, and a polymerization initiator, forming a pattern, and baking the formed pattern, the cross section shape of the pattern before baking easily becomes an undercut shape.

In general, as the cross section shape of the pattern, the undercut shape is not a desired shape, a rectangular or a tapered shape is desirable shape, and a tapered shape having a great rectangular or taper angle to some extent is more desirable shape.

Here, the undercut shape indicates the cross section shape of the pattern in which the upper portion of the pattern edge which is protruded in an eave shape towards a pattern non-formation region. The undercut shape is referred to as a “reverse tapered shape”.

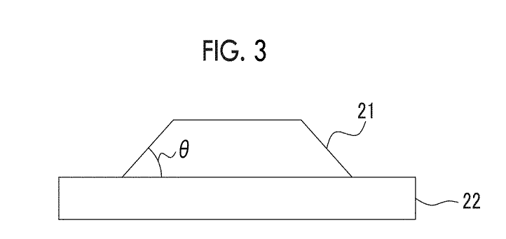

A rectangular shape indicates the cross section shape of the pattern in which a portion of the undercut shape protruded in an eave shape (hereinafter, also referred to as an “eave portion”) is not present, and a taper angle which is an angle formed by a contact surface with a base material of a pattern and a side surface of a pattern (for example, taper angle θ in FIG. 3 which will be described later) is 90°.

The tapered shape indicates the cross section shape of a pattern in which the eave portion is not present and the taper angle is equal to or greater than 0° and smaller than 90°.

In addition, the tapered shape having a great taper angle to some extent indicates a tapered shape in which the taper angle is equal to or greater than 30° and smaller than 90° (more preferably equal to or greater than 60° and smaller than 90°).

In a case where the cross section shape of a pattern is the undercut shape (reverse tapered shape), the taper angle is greater than 90°.

The tapered shape (forward tapered shape), the undercut shape (reverse tapered shape), the rectangular shape, and the taper angle are well known in the technical field of the photosensitive resin composition.

It is thought that, in a case of performing the exposure and development of the photosensitive resin layer including solid contents of a so-called negative photosensitive resin composition, forming a pattern, and baking the formed pattern, a reason that the cross section shape of a pattern before baking easily becomes the undercut shape is because a lower degree of curing of the inner portion of the photosensitive resin layer, compared to a degree of curing of the surface of the photosensitive resin layer, due to the exposed light which hardly approaches the inner portion of the photosensitive resin layer.

This tendency particularly significant occurs, in a case where the photosensitive resin layer includes the pigment (particularly, black pigment), content of which is equal to or greater than 20% by mass with respect to a total amount of solid contents of the photosensitive resin layer.

Even in a case where the cross section shape of a pattern before baking is the undercut shape, in a case where this pattern is baked at a baking temperature of the related art (for example, 240° C.), heat sagging (deformation) of the eave portion of the pattern edge is caused due to the baking heat, and the cross section shape of the pattern is easily changed to a tapered shape or a rectangular shape.

However, in a case where the baking temperature after the development is set as a low temperature (for example, equal to or lower than 200° C.), in the pattern formation using the photosensitive resin composition disclosed in JP2009-134263 and JP2007-256683 described above, for example, the heat sagging of the pattern is insufficient, and accordingly, the undercut shape after the development (that is, the undesired shape) may be maintained, even after the baking.

Regarding this point, it is thought that, in the photosensitive resin composition of the embodiment, by setting the Mw of the specific binder to be equal to or smaller than 25,000, the heat sagging of the pattern is promoted. Accordingly, it is thought that, even in a case where the baking temperature after the development is set as a low temperature (for example, equal to or lower than 200° C.), the cross section shape of the pattern after the baking can be set as an excellent cross section shape (that is, a tapered shape or a rectangular shape) using the heat sagging of the pattern.

For example, a resin base material is normally used in a touch panel.

Accordingly, in a case of forming the decorative pattern of a touch panel including a decorative pattern by processes of the exposure, the development, and the baking, it is necessary to set the temperature of the baking to be a low temperature (for example, equal to or lower than 200° C.), compared to the baking temperature of the related art (for example, 240° C.) for forming a black matrix or the like of a color filter.

Regarding this point, even in a case where the baking temperature after the development of the photosensitive resin composition of the embodiment is set as a low temperature (for example, equal to or lower than 200° C.) as described above, the cross section shape of the pattern after the baking can be set as an excellent cross section shape (that is, a tapered shape or a rectangular shape).

Accordingly, the photosensitive resin composition of the embodiment is particularly suitable for the formation of a decorative pattern of a touch panel including a decorative pattern.

<Specific Binder>

The photosensitive resin composition of the embodiment includes at least one kind of a binder (specific binder) having an I/O value equal to or greater than 0.5 and Mw equal to or smaller than 25,000.

As the specific binder, a resin, at least a part of which can be dissolved due to a contact with an alkali solvent (for example, a developer which is a carbonate aqueous solution) can be used, for example.

By setting the I/O value of the specific binder to be equal to or greater than 0.5, the developability tends to be improved, even in a case of using a developer which is a carbonate aqueous solution as described above.

The upper limit of the I/O value of the specific binder is not particularly limited. The upper limit of the I/O value of the specific binder is, for example, 0.9.

In this specification, the I/O value is a parameter showing a scale of hydrophilicity/lipophilicity of the binder.

Regarding the I/O value, “Organic Conceptual Diagram” (written by Yoshio Koda, Sankyo Publishing, 1984) can be referred to.

The I/O value of the binder close to 0 (zero) means that polarity of the binder is small (that is, lipophilicity and organicity of the binder are great), and a great value of the I/O value of the binder means that the polarity of the binder is great (that is, hydrophilicity and inorganicity of the binder are great) (for example, see JP2007-256683A and JP2009-134263A).

In the embodiment, I (hydrophilicity) and O (lipophilicity) are respectively calculated based on a chemical structure of the binder and the I/O value was calculated.

By setting the Mw of the specific binder to be equal to or smaller than 25,000, the developability tends to be improved, even in a case of using the developer which is a carbonate aqueous solution as described above.

In addition, by setting the Mw of the specific binder to be equal to or smaller than 25,000, the cross section shape of the pattern after baking can be set as an excellent cross section shape, even in a case of performing the baking at a low temperature (equal to or lower than 200° C.) as described above.

From a viewpoint of preventing fragments in a plan view of the pattern (hereinafter, also referred to as “pattern fragments”), the Mw of the specific binder is preferably equal to or greater than 4,000.

In a case where the Mw of the specific binder is equal to or greater than 4,000, an effect of preventing tacking (stickiness) of the pattern to be formed is also obtained.

Therefore, in a case where a transfer film which will be described later includes a protective film, peeling properties of the protective film are improved.

The weight-average molecular weight of the specific binder is preferably 4,000 to 20,000, more preferably 5,000 to 15,000, and even more preferably 5,000 to 10,000.

In the specification, the measurement of the weight-average molecular weight of the binder can be performed by gel permeation chromatography (GPC) under the following conditions. A calibration curve is drawn from eight samples of “STANDARD SAMPLES TSK standard, polystyrene” manufactured by Tosoh Corporation: “F-40”, “F-20”, “F-4”, “F-1”, “A-5000”, “A-2500”, “A-1000”, “n-propylbenzene”.

—Conditions—
GPC: HLC (registered trademark)-8020 GPC (manufactured by Tosoh Corporation)
   Column: TSKgel (registered trademark), three Super Multipore HZ-H (manufactured by Tosoh Corporation, 4.6 mmID×15 cm)
Eluent: Tetrahydrofuran (THF)
Sample Concentration: 0.45% by mass
Flow rate: 0.35 ml/min
Sample injected amount: 10 μL
Measurement temperature: 40° C.
Detector: differential refractometer (RI)

As the specific binder, for example, a resin having the I/O value and Mw described above can be used, among the resins disclosed in a paragraph [0025] of JP2011-095716A and paragraphs [0033] to [0052] of JP2010-237589A.

From a viewpoint of exhibiting more excellent pattern forming properties, a binder including a carboxy group is preferable as the specific binder.

In a case where the specific binder is a binder including a carboxy group, pattern fragments are prevented and a so-called edge roughness of the pattern tends to be improved.

Specific examples of the specific binder include a random copolymer of benzyl (meth)acrylate/(meth)acrylic acid, a random copolymer of styrene/(meth)acrylic acid, a copolymer of cyclohexyl (meth)acrylate/(meth)acrylic acid/methyl (meth)acrylate, a glycidyl (meth)acrylate adduct of a copolymer of cyclohexyl (meth)acrylate/methyl (meth)acrylate/(meth)acrylic acid, a glycidyl (meth)acrylate adduct of a copolymer of benzyl (meth)acrylate/(meth)acrylic acid, a copolymer of allyl (meth)acrylate/(meth)acrylic acid, and a copolymer of benzyl (meth)acrylate/(meth)acrylic acid/hydroxyethyl (meth)acrylate.

As the specific binder, a commercially available product may be used, and examples thereof include ACRYLIC-BASED (registered trademark) FFS-6058 and FF187 manufactured by Fujikura Kasei Co., Ltd. and 8 KB series such as ACRIT (registered trademark) 8 KB-001 manufactured by Taisei Fine Chemical Co., Ltd.

An acid value of the specific binder is preferably equal to or greater than 50 mgKOH/g, more preferably equal to or greater than 70 mg/KOH, and more preferably equal to or greater than 100 mg/KOH.

In a case where the acid value of the specific binder is equal to or greater than 50 mg/KOH, the developability is further improved.

The upper limit of the acid value of the specific binder is not particularly limited.

From a viewpoint of further preventing the pattern fragments due to the development, the acid value of the specific binder is preferably equal to or smaller than 200 mg/KOH.

The acid value of the specific binder can be measured by the following method, for example.
(1) Propylene glycol monomethyl ether acetate is added to a specific binder solution (y (g)) having a concentration of solid contents (x (%)) for dilution, and a sample solution having a concentration of solid contents of 1% by mass to 10% by mass is produced.
(2) The titration is performed with respect to the sample solution with a potassium hydroxide.ethanol solution (tilter a) having a concentration of 0.1 mol/L using a potential difference measurement device (device name “HIRANUMA AUTOMATIC TITRATOR COM-550” manufactured by Hiranuma Sangyo Co., Ltd.), and the amount (b (mL)) of potassium hydroxide.ethanol solution necessary for the end of the titration is measured.
(3) The titration is performed with respect to water by the same method as in (2), and the amount (c (mL)) of potassium hydroxide.ethanol solution necessary for the end of the titration is measured.
(4) The solid content acid value of the resin is determined by the calculation performed using the following equation.

Solid content acid value (mgKOH/g)={5.611×(b−c)×a}/{(x/100)×y}

The content of the specific binder in the photosensitive resin composition is preferably equal to or greater than 5% by mass, more preferably equal to or greater than 10% by mass, even more preferably equal to or greater than 20% by mass, and particularly preferably equal to or greater than 30% by mass, with respect to a total amount of solid contents of the composition.

The content of the specific binder in the photosensitive resin composition is preferably equal to or smaller than 75% by mass, more preferably equal to or smaller than 70% by mass, even more preferably equal to or smaller than 60% by mass, and particularly preferably equal to or smaller than 50% by mass, with respect to a total amount of solid contents of the composition.

The photosensitive resin composition of the embodiment may include a binder other than the specific binder.

A preferred aspect of the other binder is the same as the preferred aspect of the specific binder, other than the I/O value and the Mw.

In a case where the photosensitive resin composition of the embodiment includes the other binder, the content of the other binder is preferably equal to or smaller than 10% by mass with respect to a total amount of solid contents of the photosensitive resin composition of the embodiment.

The content of the specific binder in the photosensitive resin composition of the embodiment is preferably equal to or greater than 50% by mass, more preferably equal to or greater than 60% by mass, even more preferably equal to or greater than 70% by mass, and particularly preferably equal to or greater than 80% by mass with respect to a total amount of the included binder.

The upper limit of the content of the specific binder in the photosensitive resin composition of the embodiment is not particularly limited. The content of the specific binder in the photosensitive resin composition of the embodiment may be 100% by mass with respect to a total amount of the included binder.

A ratio of a total content mass of the polymerizable monomer with respect to a total content mass of the binder in the photosensitive resin composition of the embodiment (hereinafter, also referred to as a “polymerizable monomer/binder ratio” or an “M/B ratio”) is preferably 0.10 to 0.50, more preferably 0.32 to 0.38, and particularly preferably 0.32 to 0.36.

The total content mass of the binder here means a total content mass of the binder included in the photosensitive resin composition, and means a total content mass of the specific binder and the binder other than the specific binder, in a case where the photosensitive resin composition includes the specific binder and the binder other than the specific binder. For example, in Table 1 which will be described later, the total content mass of the binder of Example 1 is a total content mass of a polymer 1 as the specific binder and a dispersion binder in a black pigment dispersion liquid as the other binder.

In a case where the M/B ratio is equal to or greater than 0.10, the developability is further improved (particularly, a period of development time is further shortened).

In a case where the M/B ratio is equal to or smaller than 0.50, the pattern fragments are further prevented.

<Pigment>

The photosensitive resin composition of the embodiment includes at least one kind of a pigment.

Accordingly, the formation of a colored pattern (for example, decorative pattern of a touch panel) can be performed.

The pigment is not particularly limited and can be suitably selected according to the purpose. Examples thereof include well-known organic pigment and inorganic pigment, and also include commercially available pigment dispersion or surface-treated pigment (for example, a component in which a pigment is dispersed in water, a liquid compound, or an insoluble resin as a dispersion medium, or a pigment having a surface treated with a resin or a pigment derivative).

Examples of the organic pigment and the inorganic pigment include a black pigment, a white pigment, a blue pigment, a cyan pigment, a green pigment, an orange pigment, a violet pigment, a brown pigment, a yellow pigment, a red pigment, and a magenta pigment.

From a viewpoint of obtaining a pattern having high optical density, a black pigment, a white pigment, a blue pigment, a red pigment, a yellow pigment, or a green pigment is preferable, and a black pigment is more preferable among the pigments.

For example, in a case of using the photosensitive resin composition of the embodiment for the formation of a decorative pattern of a touch panel, the photosensitive resin composition of the embodiment preferably includes the black pigment.

As the black pigment, a well-known black pigment, for example, a black pigment selected from an organic pigment and an inorganic pigment can be suitably used.

The concept of the inorganic pigment includes a pigment including a metal compound such as a metal pigment or a metal oxide pigment.

From a viewpoint of improving optical density of the photosensitive resin layer to be formed, examples of the black pigment include carbon black, titanium carbon, iron oxide, a titanium oxide pigment (for example, titanium black), and graphite, and among these, carbon black is preferable.

The carbon black is also available as a commercial product, and black pigment dispersion FDK-911 [product name: FDK-911] manufactured by Tokyo Printing Ink Mfg Co., Ltd. is used, for example.

From a viewpoint of further improving uniform dispersibility of the carbon black in the photosensitive resin layer, the carbon black is preferably carbon black having a surface coated with a resin (hereinafter, also referred to as a “resin-coated carbon black”).

Regarding the coating of the carbon black with a resin in the resin-coated carbon black, at least a part of the surface of the carbon black may be coated or the entire surface thereof may be coated.

The resin-coated carbon black can be produced by a method disclosed in paragraphs

to [0042] of JP5320652B, for example. In addition, the resin-coated carbon black is also available as a commercial product, and SF Black GB 4051 manufactured by Sanyo Color Works, Ltd. is used.

A particle diameter of the black pigment is preferably 0.001 μm to 0.3 μm and more preferably 0.01 μm to 0.2 μm, in terms of a number average particle diameter, from a viewpoint of dispersion stability.

The “particle diameter” here indicates a diameter in a case where an image of an electron micrograph of a particle is set as a circle having the same area. In addition, the “number average particle diameter” is an average value of the particle diameters, obtained by acquiring the particle diameters of 100 random particles.

The number average particle diameter of the black pigment included in the photosensitive resin composition can be calculated by measuring particle diameters of 100 random particles included in a viewing angle using an image obtained by imaging the photosensitive resin layer including the black pigment at 300,000 times by a transmission electron microscope (JEOL), and obtaining an average value of the measured values.

A content of the pigment (for example, black pigment) in the photosensitive resin composition of the embodiment is equal to or greater than 20% by mass and more preferably equal to or greater than 30% by mass with respect to a total amount of the photosensitive resin composition, from a viewpoint of color density.

From a viewpoint of further increasing curing sensitivity of the photosensitive resin layer including solid contents of the photosensitive resin composition, the content of the pigment (for example, black pigment) in the photosensitive resin composition of the embodiment is preferably equal to or smaller than 70% by mass, more preferably equal to or smaller than 60% by mass, and particularly preferably equal to or smaller than 55% by mass.

In a case where the photosensitive resin composition of the embodiment includes the black pigment, the photosensitive resin composition is preferably produced using a dispersion liquid of the black pigment.

The dispersion liquid can be produced by adding and dispersing a composition obtained by mixing a black pigment and a pigment dispersing agent (for example, dispersion binder) in advance to an organic solvent or a vehicle which will be described later. The vehicle is a portion of a medium which causes dispersion of the pigment in a case where the photosensitive resin composition is in a liquid state, and includes a liquid component which forms the photosensitive resin layer by combining with the black pigment (for example, a binder), and a medium such as an organic solvent which causes dissolving and diluting thereof.

The dispersing device used for dispersing the black pigment is not particularly limited, and examples thereof include well-known dispersing device such as a kneader, a roll mill, an attritor, a super mill, a dissolver, a homomixer, or a sand mill disclosed in Kunizo Asakura, “Pigment Encyclopedia”, First Edition, Asakura Shoten, 2000, pp. 438. In addition, the black pigment which is a dispersoid may be finely pulverized using a friction force by a mechanical attrition disclosed in pp. 310 of the document described above.

The pigment dispersing agent may be selected according to the pigment and the solvent included in the photosensitive resin composition, or a commercially available dispersing agent can be used, for example.

<Polymerizable Monomer>

The photosensitive resin composition of the embodiment includes at least one kind of a polymerizable monomer.

As the polymerizable monomer, a monomer including at least one polymerizable group in a molecule can be used.

As the polymerizable group, an ethylenically unsaturated group or an epoxy group is used.

Among these, an ethylenically unsaturated group is preferable and a (meth)acryloyl group is more preferable.

In the photosensitive resin composition of the embodiment, the polymerizable monomer preferably includes a difunctional monomer. Accordingly, the developability is further improved.

In this case, the content of the difunctional monomer is preferably equal to or greater than 50% by mass with respect to a total amount of the polymerizable monomer.

Here, the difunctional monomer indicates a polymerizable monomer including two polymerizable groups in a molecule.

In a case where the polymerizable monomer includes a difunctional monomer (preferably, equal to or greater than 50% by mass), effects of the heat sagging promotion of the pattern and the cross section shape improvement of the pattern after the baking, described above are further effectively exhibited.

The polymerizable monomer may include at least one kind selected from the group consisting of a monofunctional monomer and a tri- or higher functional monomer.

Here, the monofunctional monomer indicates a polymerizable monomer including one polymerizable group in a molecule.

The tri- or higher functional monomer indicates a polymerizable monomer including three polymerizable groups in a molecule.

From a viewpoint of both satisfying the developability and strength of a pattern, the polymerizable monomer preferably includes a difunctional monomer and a tri- or higher functional monomer.

In a case where the polymerizable monomer includes a difunctional monomer and a tri- or higher functional monomer, a ratio of a content of the difunctional monomer with respect to a total content of the difunctional monomer and the tri- or higher functional monomer [difunctional monomer/total content of the difunctional monomer and the tri- or higher functional monomer] is preferably equal to or greater than 50% by mass, and more preferably equal to or greater than 60% by mass, from a viewpoint of developability.

In this case, the ratio [difunctional monomer/total content of the difunctional monomer and the tri- or higher functional monomer] is preferably equal to or smaller than 90% by mass and more preferably equal to or smaller than 80% by mass, from a viewpoint of strength of a pattern.

In addition, in a case where the polymerizable monomer includes a difunctional monomer and a tri- or higher functional monomer, a ratio of a total content of the difunctional monomer and the tri- or higher functional monomer with respect to a total content of the polymerizable monomer [total content of difunctional monomer and the tri- or higher functional monomer/total content of polymerizable monomer] is preferably equal to or greater than 80% by mass and more preferably equal to or greater than 90% by mass.

The content of the polymerizable monomer in the photosensitive resin composition of the embodiment is preferably equal to or greater than 5% by mass and more preferably equal to or greater than 10% by mass with respect to a total amount of solid contents of the photosensitive resin composition.

The content of the polymerizable monomer in the photosensitive resin composition of the embodiment is preferably equal to or smaller than 50% by mass, more preferably equal to or smaller than 40% by mass, and even more preferably equal to or smaller than 30% by mass with respect to a total amount of solid contents of the photosensitive resin composition.

Examples of the polymerizable monomer include monofunctional (meth)acrylate such as polyethylene glycol mono (meth)acrylate, polypropylene glycol mono (meth)acrylate, and phenoxyethyl (meth)acrylate; and polyfunctional (meth)acrylate such as polyethylene glycol di (meth)acrylate, polypropylene glycol di (meth)acrylate, trimethylolethane triacrylate, trimethylolpropane triacrylate, trimethylolpropane diacrylate, neopentyl glycol di (meth)acrylate, pentaerythritol tetra (meth)acrylate, pentaerythritol tri (meth)acrylate, dipentaerythritol hexa (meth)acrylate, dipentaerythritol penta (meth)acrylate, hexanediol di (meth)acrylate, trimethylolpropane tri (acryloyloxypropyl) ether, tri (acryloyloxyethyl) isocyanurate, tri (acryloyloxyethyl) cyanurate, glycerin tri (meth)acrylate; a component obtained by (meth)acrylating after adding propylene oxide to ethylene oxide of polyfunctional alcohol such as trimethylolpropane or glycerin.

In addition, a urethane type monomer such as a urethane (meth)acrylate compound can be also preferably used.

Examples thereof further include polyfunctional (meth)acrylate such as urethane acrylates disclosed in JP1973-041708B (JP-S48-041708B), JP1975-006034B (JP-S50-006034B), and JP1976-037193A (JP-S51-037193A); polyester acrylates disclosed in JP1973-064183A (JP-S48-064183A), JP974-043191B (JP-S49-043191B), JP1977-030490B (JP-S52-030490B); and epoxy acrylates which are reaction products of an epoxy resin and (meth)acrylic acid.

Among these, polyfunctional (meth)acrylate is preferable from a viewpoint of curing properties.

In addition, a urethane (meth)acrylate compound is preferable, from viewpoints of curing properties and bendability of the formed layer.

As the polymerizable monomer, a commercially available product may be used.

Preferable examples of the commercially available product include tricyclodecanedimethanol diacrylate (A-DCP, Shin-Nakamura Chemical Co., Ltd., difunctional, molecular weight of 304), tricyclodecanedimenanol dimethacrylate (DCP, Shin-Nakamura Chemical Co., Ltd., difunctional, molecular weight of 332), 1,9-nonanediol diacrylate (A-NOD-N, Shin-Nakamura Chemical Co., Ltd., difunctional, molecular weight of 268), 1,6-hexanediol diacrylate (A-HD-N, Shin-Nakamura Chemical Co., Ltd., difunctional, molecular weight of 226), 9,9-bis [4-(2-acryloyloxyethoxy) phenyl] fluorene (A-BPEF, Shin-Nakamura Chemical Co., Ltd., difunctional, molecular weight of 546), urethane acrylate (UA-160TM, Shin-Nakamura Chemical Co., Ltd., difunctional, molecular weight of 1,600), 1,6-hexanediol diacrylate (V #230, Osaka Organic Chemical Industry Ltd., difunctional, molecular weight of 226), 1,3-adamantyl diacrylate (ADDA, Mitsubishi Gas Chemical Company, Inc., difunctional, molecular weight of 276), trimethylolpropane triacrylate (A-TMPT, Shin-Nakamura Chemical Co., Ltd., trifunctional, molecular weight of 296), trimethylolpropane ethylene oxide (EO)-modified (n≈1) triacrylate (M-350, Toagosei Co., Ltd., trifunctional), pentaerythritol tetraacrylate (A-TMMT, Shin-Nakamura Chemical Co., Ltd., tetrafunctional, molecular weight of 352), dipentaerythritol hexaacrylate (A-DPH, Shin-Nakamura Chemical Co., Ltd., hexafunctional, molecular weight of 578), pentaerythritol triacrylate hexamethylene diisocyanate urethane prepolymer (UA-306 H, Kyoeisha Chemical Co., Ltd., hexafunctional), pentaerythritol triacrylate toluene diisocyanate urethane prepolymer (UA306T, Kyoeisha Chemical Co., Ltd., hexafunctional), dipentaerythritol hexaacrylate (KAYARAD DPHA, Nippon Kayaku Co., Ltd., hexafunctional, molecular weight of 579), urethane (meth)acrylate (UA-32P, Shin-Nakamura Chemical Co., Ltd., nona-functional), urethane (meth)acrylate (8UX-015A, Taisei Fine Chemical Co., Ltd., 15-functional, molecular weight of 2,078).

A molecular weight of the polymerizable monomer is preferably equal to or smaller than 3,000, more preferably equal to or smaller than 2,000, even more preferably equal to or smaller than 1,000, and particularly preferably equal to or smaller than 500.

In a case where the molecular weight of the polymerizable monomer is equal to or smaller than 500, the heat sagging in low-temperature baking easily occurs.

The molecular weight of the polymerizable monomer can be obtained from a molecular formula by identifying a molecular structure by mass spectrography (for example, liquid chromatograph (LC/MS) analysis, gas chromatograph (GC/MS) analysis, or fast atom bombardment chromatograph (FAB/MS analysis)).

<Polymerization Initiator>

The photosensitive resin composition of the embodiment includes at least one kind of the polymerization initiator.

Examples of the polymerization initiator include a polymerization initiator disclosed in paragraphs [0031] to [0042] of JP2011-095716A and an oxime-based polymerization initiator disclosed in paragraphs [0064] to [0081] of JP2015-014783A.

As the oxime-based polymerization initiator, an oxime ester type compound can be used.

As the polymerization initiator, a commercially available product can be used.

Examples of the commercially available product preferably include 1,2-octanedione-1-[4-(phenylthio)-2-(O-benzoyloxime)] (product name: IRGACURE OXE-01, BASF Japan Ltd.), Ethan-1-one, [9-ethyl-6-(2-methylbenzoyl)-9H-carbazol-3-yl]-1-(0-acetyloxime) (product name: IRGACURE OXE-02, BASF Japan Ltd.), 2-(dimethylamino)-2-[(4-methylphenyl) methyl]-1-[4-(4-morpholinyl) phenyl]-1-butanone (product name: IRGACURE 379EG, BASF Japan Ltd.), 2-methyl-1-(4-methylthiophenyl)-2-morpholinopropan-1-one (product name: IRGACURE 907, BASF Japan Ltd.), 2-hydroxy-1-{4-[4-(2-hydroxy-2-methyl-propionyl)-benzyl] phenyl}-2-methyl-propan-1-one (product name: IRGACURE 127, BASF Japan Ltd.), 2-benzyl-2-dimethylamino-1-(4-morpholinophenyl)-butanone-1 (product name: IRGACURE 369, BASF Japan Ltd.), 2-hydroxy-2-methyl-1-phenyl-propan-1-one (product name: IRGACURE 1173, BASF Japan Ltd.), 1-hydroxy-cyclohexyl-phenyl-ketone (product name: IRGACURE 184, BASF Japan Ltd.), 2,2-dimethoxy-1,2-diphenylethan-1-one (product name: IRGACURE 651, BASF Japan Ltd.), and a product name of an oxime ester type: Lunar 6 (DKSH Management Ltd.), 2,4-diethylthioxanthone (product name: KAYACURE DETX-S, Nippon Kayaku Co., Ltd.), and DFI-091 and DFI-020 which is a fluorene oxime type polymerization initiator (both, DAITO CHEMIX Co., Ltd.).

As the polymerization initiator, a polymerization initiator other than a halogen-containing polymerization initiator (for example, a trichloromethyl triazine-based compound used for a color filter material or the like) is preferably used, from a viewpoint of increasing sensitivity.

Specifically, as the polymerization initiator, a α-aminoalkylphenone-based polymerization initiator, a α-hydroxyalkylphenone-based polymerization initiator, or an oxime-based polymerization initiator is more preferable, and an oxime-based polymerization initiator is particularly preferable, from a viewpoint of further improving sensitivity in a case of the pattern formation.

A content of the polymerization initiator in the photosensitive resin composition of the embodiment is preferably greater than 0% by mass and smaller than 9% by mass and more preferably greater than 0% by mass and smaller than 4$ by mass with respect to a total amount of solid contents of the photosensitive resin composition.

In a case where the content of the polymerization initiator is smaller than 9% by mass, the developability is further improved, and the heat sagging of a pattern is promoted (that is, the cross section shape of a pattern after baking is further improved).

The content of the polymerization initiator is preferably equal to or greater than 0.5% by mass, more preferably equal to or greater than 1% by mass, and even more preferably equal to or greater than 2% by mass with respect to a total amount of solid contents of the photosensitive resin composition.

A ratio of a total content mass of the polymerization initiator with respect to a total content mass of the polymerizable monomer in the photosensitive resin composition of the embodiment (hereinafter, also referred to as a “polymerization initiator/polymerizable monomer ratio”) is preferably 0.05 to 0.50 and more preferably 0.07 to 0.30.

In a case where the polymerization initiator/polymerizable monomer ratio is equal to or greater than 0.05, the cross section shape of the formed pattern is further improved.

In a case where the polymerization initiator/polymerizable monomer ratio is equal to or smaller than 0.50, precipitate of the polymerization initiator from the photosensitive resin layer including solid contents of the photosensitive resin composition is further prevented.

<Polymerization Inhibitor>

The photosensitive resin composition of the embodiment may include at least one kind of a polymerization inhibitor.

In a case where the photosensitive resin composition of the embodiment includes the polymerization inhibitor, the occurrence of the development residue is further prevented.

As the polymerization inhibitor, a thermal polymerization preventing agent (also referred to as a polymerization inhibitor) disclosed in a paragraph [0018] of JP4502784B can be used, for example.

Among these, phenothiazine and phenoxazine or 4-methoxyphenol can be suitably used.

In a case where the photosensitive resin composition of the embodiment includes the polymerization inhibitor, a content of the polymerization inhibitor is preferably 0.01% by mass to 3% by mass, more preferably 0.05% by mass to 1% by mass, and even more preferably 0.1% by mass to 0.8% by mass with respect to a total solid content of the photosensitive resin composition.

<Other Components>

The photosensitive resin composition of the embodiment may include a dye, a thiol compound, a solvent, and the like, in addition to the components described above.

(Dye)

The dye which may be included in the photosensitive resin composition is not particularly limited. A well-known dye, for example, a well-known dye disclosed in a document such as “Handbook of Dyes” (edited by The Society of Synthetic Organic Chemistry, Japan, published in 1970), or a dye available as a commercial product can be suitably selected and used.

Specific examples of dye include dyes such as an azo dye, a metal complex azo dye, a pyrazolone azo dye, a naphthoquinone dye, an anthraquinone dye, a phthalocyanine dye, a carbonium dye, a quinoneimine dye, a methine dye, a cyanine dye, a squarylium dyes, pyrylium salt, and a metal thiolate complex.

In a case where the photosensitive resin composition of the embodiment includes the dye, a content of the dye is preferably 1 parts by mass to 40 parts by mass and more preferably 1 parts by mass to 20 parts by mass with respect to 100 parts by mass of the pigment described above, from a viewpoint of exhibiting antireflection ability. In a case where the content of the dye is in the range described above, the antireflection effect of the photosensitive resin layer to be formed, that is, a visual glare prevention effect is improved.

(Thiol Compound)

It is preferable that the photosensitive resin composition of the embodiment includes the thiol compound, from a viewpoint of further increasing sensitivity in a case of the pattern formation.

A functional number of the thiol compound which is the number of thiol groups (also referred to as a mercapto group) may be monofunctional, or difunctional or higher.

In a case where the photosensitive resin composition of the embodiment includes the thiol compound, the thiol compound is preferably a di- or higher functional compound, more preferably di- to tetrafunctional compound, and particularly preferably a di- or trifunctional compound, from a viewpoint of further increasing the sensitivity.

As the monofunctional thiol compound which can be included in the photosensitive resin composition, N-phenylmercaptobenzimidazole is used.

Examples of the di- or higher functional thiol compound which can be included in the photosensitive resin composition include 1,4-bis (3-mercaptobutyryloxy) butane (KARENZ MT BD1, manufactured by SHOWA DENKO K.K.), 1,3,5-tris (3-mercaptobutyryloxyethyl)-1,3,5-triazine-2,4,6 (1H,3H,5H)-trione (KARENZ MT NR1, manufactured by SHOWA DENKO K.K.), pentaerythritol tetrakis (3-mercaptobutyrate) (KARENZ MT PE 1, manufactured by SHOWA DENKO K.K.), and pentaerythritol tetrakis (3-mercaptopropionate) (“PEMP” manufactured by Sakai Chemical Industry Co., Ltd.).

(Additive)

The photosensitive resin composition of the embodiment may include an additive. Examples of the additive include a surfactant disclosed in a paragraph [0017] of JP4502784B and paragraphs [0060] to [0071] of JP2009-237362A, and other additives disclosed in paragraphs [0058] to [0071] of JP2000-310706A.

As the surfactant, a fluorine-containing surfactant, for example, MEGAFACE (registered trademark) F-784-F and F-780F manufactured by DIC Corporation is preferably used, from a viewpoint of improving film properties in a case of coating and forming the photosensitive resin layer.

(Solvent)

The photosensitive resin composition of the embodiment preferably further includes a solvent.

Accordingly, the formation of the photosensitive resin layer by coating is easily performed.

As the solvent, a solvent generally used can be used, without particular limitation. Specific examples of the solvent include ester, ether, ketone, and aromatic hydrocarbon.

In the same manner as Solvent disclosed in paragraphs [0054] and [0055] of US2005/282073A1, methyl ethyl ketone, propylene glycol monomethyl ether, propylene glycol monomethyl ether acetate (hereinafter, referred to as PEGMEA), cyclohexanone, cyclohexanol, methyl isobutyl ketone, ethyl lactate, and methyl lactate can be suitably used in the photosensitive resin composition.

Among the solvents described above, 1-methoxy-2-propyl acetate, methyl 3-ethoxypropionate, ethyl 3-ethoxypropionate, ethyl cellosolve acetate, ethyl lactate, butyl acetate, methyl 3-methoxypropionate, 2-heptanone, cyclohexanone, diethylene glycol monoethyl ether acetate (ethyl carbitol acetate), diethylene glycol monobutyl ether acetate (butyl carbitol acetate), propylene glycol methyl ether acetate, and methyl ethyl ketone are preferably used as the solvent.

In a case where the photosensitive resin composition includes the solvent, the solvent may be used alone or in combination of two or more kinds thereof.

As the solvent, an organic solvent having a boiling point of 180° C. to 250° C. (high-boiling-point solvent) can be used, if necessary.

[Transfer Film]

A transfer film of the embodiment includes a temporary support, and a photosensitive resin layer including solid contents of the photosensitive resin composition of the embodiment described above.

In a case of forming a pattern on a base material using the transfer film of the embodiment, the photosensitive resin layer of the transfer film of the embodiment is transferred to the base material, on which a pattern is to be formed, and the exposure, the development, and the baking after the development are performed with respect to the photosensitive resin layer transferred onto the base material in this order, and a pattern is formed on the base material.

According to the transfer film of the embodiment, the same effect as the effect of the photosensitive resin composition of the embodiment is exhibited.

The transfer film of the embodiment can be used without particularly limitation of the use of the pattern formation, and particularly, is suitable for forming a decorative pattern of a touch panel including a decorative pattern.

The photosensitive resin layer of the transfer film includes the solid contents of the photosensitive resin composition of the embodiment.

That is, in a case where the photosensitive resin composition of the embodiment includes the solvent, the photosensitive resin layer of the transfer film includes at least components (that is, solid contents) other than the solvent of the photosensitive resin composition. In this case, the photosensitive resin layer may further include a solvent. As the case where the photosensitive resin layer includes the solvent, for example, a case where the solvent remains in the photosensitive resin layer even after the drying, in a case of forming the photosensitive resin layer by applying and drying the photosensitive resin composition including the solvent is used.

In a case where the photosensitive resin composition of the embodiment does not include a solvent, the photosensitive resin layer of the transfer film includes all of the components of the photosensitive resin composition.

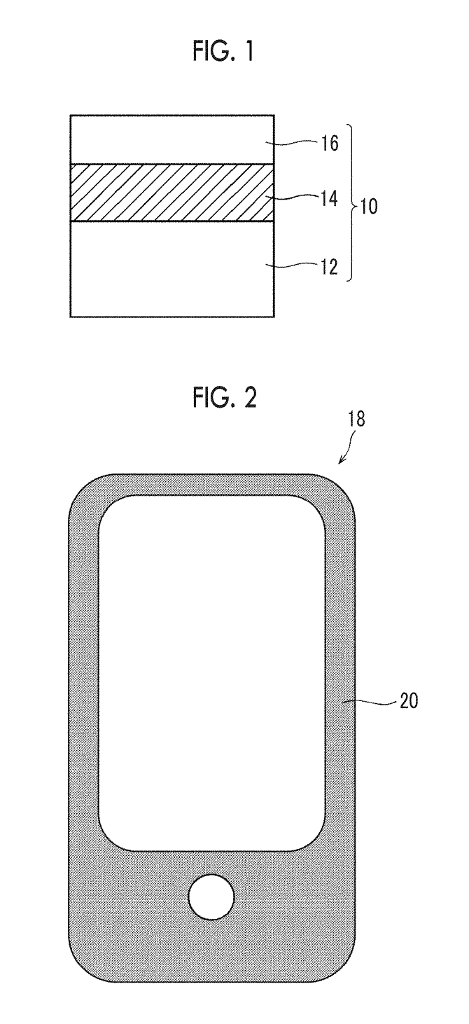

FIG. 1 is a schematic cross sectional view showing an example of the configuration of the transfer film of the embodiment.

A transfer film 10 shown in FIG. 1 includes a temporary support 12, a black resin layer 14 which is a photosensitive resin layer, and a protective film 16, in this order.

FIG. 1 shows the transfer film 10 having an aspect in which the temporary support 12, the black resin layer 14, and the protective film 16 are laminated to be adjacent to each other, but the configuration of the transfer film of the embodiment is not limited to this aspect. As will be described later, the transfer film of the embodiment, for example, may include a thermoplastic resin layer (not shown) between the temporary support 12 and the black resin layer 14, or may include a functional layer (not shown) between the black resin layer 14 and the thermoplastic resin layer which is randomly provided.

<Photosensitive Resin Layer>

The transfer film of the embodiment includes a photosensitive resin layer including solid contents of the photosensitive resin composition of the embodiment described above.

The components included in the photosensitive resin composition and the preferred aspects thereof are as described above.

A thickness of the photosensitive resin layer of the transfer film is preferably 0.5 μm to 10.0 μm, more preferably 1.0 μm to 8.0 μm, and even more preferably 1.5 μm to 5.0 μm.

<Temporary Support>

The transfer film of the embodiment includes a temporary support.

As the temporary support, a film having flexibility can be used.

Examples of the temporary support include a cycloolefin copolymer film, a polyethylene terephthalate (hereinafter, may be referred to as “PET”) film, a cellulose triacetate film, a polystyrene film, a polycarbonate film, and a polyolefin film (for example, polyethylene (PE) film or polypropylene (PP) film). Among these, from a viewpoint of handling, the PET film is particularly preferable.

The temporary support may be transparent or may be colored by including dyeing silicon, alumina sol, chromium salt, zirconium salt, or the like.

Conductivity can be applied to the temporary support by a method disclosed in JP2005-221726A.

<Functional Layer>

The transfer film of the embodiment may include a functional layer between the temporary support and the photosensitive resin layer.

As the functional layer, an oxygen insulating layer is preferable.

In a case where the transfer film includes the oxygen insulating layer, exposure sensitivity in a case of exposing the photosensitive resin layer transferred onto the base material is improved. Accordingly, a time load of an exposure device decreases and productivity is improved.

As the oxygen insulating layer, a layer which shows low oxygen permeability and is dispersed or dissolved in water or an alkali aqueous solution is preferable, and a well-known oxygen insulating layer can be used.

The oxygen insulating layer preferably includes polyvinyl alcohol and polyvinyl pyrrolidone.

A thickness of the functional layer (for example, oxygen insulating layer) is preferably 0.2 μm to 5 μm, more preferably 0.5 μm to 3 μm, and particularly preferably 1.0 μm to 2.5 μm.

<Thermoplastic Resin Layer>

The transfer film of the embodiment may include a thermoplastic resin layer between the temporary support and the photosensitive resin layer (in a case of including the oxygen insulating layer, between the temporary support and the oxygen insulating layer).

The thermoplastic resin layer is preferably a cushioning layer which functions as a cushion in a case of transferring the photosensitive resin layer of the transfer film to the base material.

As a component which may be included in the thermoplastic resin layer, an organic polymer substance disclosed in JP1993-072724 (JP-H05-072724A) is preferable, and an organic polymer substance having a softening point approximately equal to or lower than 80° C. by Vicat method (specifically, polymer softening point measurement method based on America material test method ASTMD 1235) is particularly preferable.

Specific examples of the component which may be included in the thermoplastic resin layer include organic polymers such as polyolefin such as polyethylene or polypropylene; a copolymer of ethylene and vinyl acetate or a saponified product, or an ethylene copolymer of ethylene, acrylic ester, or saponified product thereof; polyvinyl chloride; a vinyl chloride copolymer such as vinyl chloride and vinyl acetate or a saponified product thereof; polyvinylidene chloride; a vinylidene chloride copolymer; polystyrene; a styrene copolymer such as a copolymer of styrene and (meth)acrylic acid ester or a saponified product thereof; polyvinyltoluene; a vinyltoluene copolymer such as a copolymer of vinyltoluene and (meth)acrylic acid ester or a saponified product thereof; poly (meth)acrylc acid ester; a (meth)acrylic acid copolymer such as a copolymer of butyl (meth)acrylate and vinyl acetate; a vinyl acetate copolymer; and a polyamide resin such as nylon, copolymer nylon, N-alkoxymethylated nylon, or N-dimethylaminated nylon.

A thickness of the thermoplastic resin layer is preferably 2 μm to 30 μm, more preferably 5 μm to 20 μm, and particularly preferably 7 μm to 16 μm.

<Protective Film>

The Transfer film of the embodiment may include a protective film on the photosensitive resin layer disposed on the temporary support, in order to protect the transfer film from contamination or scratches due to impurities such as dust during the storage.

As the protective film, a film which can be easily peeled off from the photosensitive resin layer can be used, and the protective film can be suitably selected from films including the material same as or similar to the material of the temporary support. As the protective film, a polyolefin film (for example, a polyethylene (PE) film or a polypropylene (PP) film), a polyethylene terephthalate film, a silicon paper, or a polytetrafluoroethylene film is suitable.

As the protective film, a protective film disclosed in paragraphs [0083] to [0087] and

of JP2006-259138A can be suitably used.

Since the transfer film of the embodiment includes the photosensitive resin layer including solid contents of the photosensitive resin composition described above, the tacking of the photosensitive resin layer is prevented. Therefore, the peeling properties of the protective film which may be disposed on the photosensitive resin layer are improved.

As one aspect of the transfer film of the embodiment, an aspect of the transfer film including a laminated structure in which the temporary support, the thermoplastic resin layer, the functional layer, the photosensitive resin layer, and the protective film are disposed in this order is used. The laminated structure in this case is also shown as a “laminated structure of protective film/photosensitive resin layer/functional layer/thermoplastic resin layer/temporary support”, hereinafter.

The transfer film of the embodiment can be manufactured based on a manufacturing method of a curable transfer material disclosed in paragraphs [0094] to [0098] of JP2006-259138A.

That is, the manufacturing method of the transfer film includes a step of forming a photosensitive resin layer on a temporary support.

The manufacturing method of the transfer film may include a step of forming a functional layer, before the step of forming the photosensitive resin layer.

In addition, the manufacturing method of the transfer film may include a step of forming the thermoplastic resin layer, before the step of forming the photosensitive resin layer (before the step of forming the functional layer, in a case of including the step of forming the functional layer).

The transfer film including the thermoplastic resin layer and the functional layer can be suitably manufactured, for example, by applying a solution (coating solution for a thermoplastic resin layer) obtained by dissolving a thermoplastic organic polymer and an additive, used in combination if necessary, onto a temporary support, drying the solution to provide a thermoplastic resin layer, applying a coating solution for a functional layer produced by adding a resin and an additive to a solvent which does not dissolve the thermoplastic resin layer, onto the provided thermoplastic resin layer, drying the coating solution to laminate a functional layer, further applying a photosensitive resin composition produced using a solvent which does not dissolve the functional layer onto the laminated functional layer, and drying the photosensitive resin composition to form a photosensitive resin layer.

The components included in the photosensitive resin composition are as described above.

[Manufacturing Method of Pattern]

The manufacturing method of a pattern of the embodiment (hereinafter, also referred to as a “manufacturing method of the embodiment”) includes a step of forming a photosensitive resin layer on a base material using the photosensitive resin composition of the embodiment or the transfer film of the embodiment (hereinafter, also referred to as a “photosensitive resin layer forming step”), a step of performing pattern exposure of the photosensitive resin layer formed on the base material (hereinafter, also referred to as a “exposure step”), and a step of forming a pattern by developing the pattern-exposed photosensitive resin layer with a developer (hereinafter, also referred to as a “development step”).

In the manufacturing method of the embodiment, even in a case of using or not using the transfer film, the photosensitive resin composition of the embodiment is used.

Accordingly, according to the manufacturing method of the embodiment, the same effect as the effect of the photosensitive resin composition of the embodiment (improvement of developability) is exhibited.

The manufacturing method of the embodiment is suitable as a manufacturing method of a decorative pattern of a touch panel including a decorative pattern. In this case, as the base material, a touch panel (for example, a resin base material on which an electrode pattern, a routing wiring, a light shielding conductive film, and an overcoat layer are formed) is used.

However, the manufacturing method of the embodiment is not limited to the manufacturing method of a decorative pattern of a touch panel including a decorative pattern.

<Base Material>

As the base material used in the manufacturing method of the embodiment, a material having no optical strain and having high transparency is preferably used.

From such a viewpoint, a glass base material or a resin base material having high transparency is preferable.

Among these, a resin base material is preferable, from viewpoints of lightness and resistance to breakage.

Specific examples of the resin base material include base materials formed of resins such as polyethylene terephthalate (PET), polyethylene naphthalate, polycarbonate (PC), triacetyl cellulose (TAC), and cycloolefin polymer (COP).

A thickness of the base material is preferably 50 μm to 200 μm.

A refractive index of the base material is preferably 1.6 to 1.78.

The base material may have a single layer structure or a laminated structure including two or more layers. In a case where the base material has a laminated structure including two or more layers, the refractive index means a refractive index of all of the layers of the base material.

A material for forming the base material is not particularly limited, as long as such a range of the refractive index is satisfied.

In a case where the base material has a laminated structure including two or more layers, the thickness means a thickness of all of the layers of the base material.

<Photosensitive Resin Layer Forming Step>

The photosensitive resin layer forming step is a step of forming a photosensitive resin layer on a base material using the photosensitive resin composition of the embodiment or the transfer film of the embodiment.

In this step, examples of the method of forming the photosensitive resin layer on the base material include a method using the transfer film of the embodiment, and a method using the photosensitive resin composition of the embodiment without using the transfer film of the embodiment.

Hereinafter, first, the method using the transfer film of the embodiment will be described.

In the method using the transfer film of the embodiment, the photosensitive resin layer is formed on the base material by transferring the photosensitive resin layer of the transfer film of the embodiment onto the base material.

The transfer of the photosensitive resin layer can be performed using a well-known laminator.

In a case of using the transfer film including a laminated structure of the protective film/photosensitive resin layer/functional layer/thermoplastic resin layer/temporary support, first, the photosensitive resin layer is exposed by peeling the protective film from the transfer film, and the transfer film and the base material are bonded to each other so that the exposed photosensitive resin layer and the base material are in contact with each other. Accordingly, the photosensitive resin layer of the transfer film is transferred onto the base material, and a laminate of the temporary support/thermoplastic resin layer/functional layer/photosensitive resin layer/base material is formed. After that, at least the temporary support is preferably peeled off from the laminate.

As an example of the method of transferring the photosensitive resin layer of the transfer film onto the base material and performing the pattern exposure and development, a description disclosed in paragraphs [0035] to [0051] of JP2006-023696A can also be referred to.

Next, the method using the photosensitive resin composition of the embodiment without using the transfer film of the embodiment will be described.

As a suitable example of this method, the photosensitive resin composition of the embodiment having an aspect of including the solvent is applied onto the base material and dried to form the photosensitive resin layer on the base material. The heat treatment (so-called pre-baking) may be performed with respect to the photosensitive resin layer after the drying and before the exposure, if necessary.

<Exposure Step>

The exposure step is a step of performing the pattern exposure of the photosensitive resin layer formed on the base material.

As the method of the pattern exposure, specifically, a method of disposing a mask, on which a predetermined pattern is formed, above the photosensitive resin layer formed onto the base material, that is, between the photosensitive resin layer and an exposure light source, and exposing the photosensitive resin layer from the above the mask.

The exposure light source can be suitably selected and used, as long as it can emit light having a wavelength region so as to cure the photosensitive resin layer (for example, 365 nm, or 405 nm).

Specifically, as the exposure light source, an ultra-high pressure mercury lamp, a high pressure mercury lamp, a metal halide lamp, and the like are used.

An exposure intensity is normally approximately 5 J/cm² to 200 mJ/cm², and is preferably approximately 10 J/cm² to 100 mJ/cm².

As the method of the pattern exposure, a method of performing scanning exposure using a laser or the like (digital exposure) is used.

In a case where the photosensitive resin layer is formed on the base material using the transfer film, the pattern exposure may be performed after peeling the temporary support, or the exposure may be performed before peeling the temporary support and then, the temporary support may be peeled off.

In the exposure step, the heat treatment (so-called post exposure bake (PEB)) may be performed with respect to the photosensitive resin layer after the pattern exposure and before the development.

<Development Step>

The development step is a step of forming a pattern by developing the pattern-exposed photosensitive resin layer with a developer.

As the developer, a well-known developer such as a developer disclosed in JP1993-072724 (JP-H05-072724A) can be used.

As the developer, a developer which can dissolve the unexposed photosensitive resin layer is preferable, and for example, a developer including 0.05 mol/L to 5 mol/L of a compound having pKa of 7 to 13 in terms of concentration is preferable.

The pH (25° C.) of the developer is preferably 8 to 13.

A small amount of an organic solvent having miscibility with water may be further added to the developer.

Examples of the organic solvent having miscibility with water include methanol, ethanol, 2-propanol, 1-propanol, butanol, diacetone alcohol, ethylene glycol monomethyl ether, ethylene glycol monoethyl ether, ethylene glycol mono-n-butyl ether, benzyl alcohol, Acetone, methyl ethyl ketone, cyclohexanone, ε-caprolactone, γ-butyrolactone, dimethylformamide, dimethylacetamide, hexamethylphosphoramide, ethyl lactate, methyl lactate, ε-caprolactam, and N-methylpyrrolidone. A concentration of the organic solvent is preferably 0.1% by mass to 30% by mass.

A well-known surfactant may be further added to the developer.

A concentration of the surfactant is preferably 0.01% by mass to 10% by mass.

In the development step, since the photosensitive resin layer including the specific binder described above is developed, the developability is excellent, even in a case where the development is performed using a developer which is a carbonate aqueous solution as described above.

As the developer which is a carbonate aqueous solution, an aqueous solution of carbonate (sodium carbonate, potassium carbonate, or the like) is used.

The developer which is a carbonate aqueous solution includes carbonate and water, and may further include other components such as an organic solvent having miscibility with water described above or a surfactant.

The pH (25° C.) of the developer which is a carbonate aqueous solution is preferably 9.0 to 12.0 and more preferably 10.0 to 12.0.

A concentration of carbonate in the developer which is a carbonate aqueous solution is preferably 0.1% by mass to 5% by mass, more preferably 0.1% by mass to 3% by mass, and even more preferably 0.5% by mass to 2% by mass.

As a method of the development, any method of paddle development, shower development, shower development and spin development, and dip development may be used.

Here, in a case of the shower development, a pattern can be formed by spraying the developer to the photosensitive resin layer after the exposure with a shower and removing the uncured material.

After the development, the development residue may be removed while spraying a cleaning agent with a shower and rubbing with a brush or the like.

A liquid temperature of the developer is preferably 20° C. to 40° C.

<Baking Step>

The manufacturing method of the embodiment preferably includes a step of baking the pattern formed by the development (hereinafter, also referred to as a “baking step”), after the development step.

The “baking” here is baking after the development, and is baking which is generally called “post baking”.

By including the baking step, the liquid component included in the pattern can be efficiently removed. In addition, by including the baking step, the cross section shape of the pattern can be set as an excellent cross section shape, using the heat sagging.

A baking temperature of the baking step is preferably equal to or lower than 200° C., more preferably equal to or lower than 180° C., and particularly preferably equal to or lower than 170° C.

In a case where the baking temperature is equal to or lower than 200° C., damage on the base material due to the heat of the baking is further prevented, even in a case of using the resin base material as the base material.

In addition, in a case where the baking temperature is equal to or lower than 200° C., even in a case of using a base material on which an electrode pattern, a routing wiring, a light shielding conductive film, and an overcoat layer are formed (for example, a touch panel) as a base material, a negative effect to these elements is decreased.

As described above, generally, in a case where the baking temperature is equal to or lower than 200° C., the heat sagging of the pattern is insufficient, and the cross section shape of the pattern after the baking may be an undercut shape.

However, in the manufacturing method of the pattern of the embodiment, since the photosensitive resin composition of the embodiment including the binder having Mw equal to or smaller than 25,000, even in a case where the baking temperature is equal to or lower than 200° C., the cross section shape of the pattern after the baking can be a rectangular or a tapered shape.

The lower limit of the baking temperature of the baking step is, for example, 130° C. and preferably 140° C.

The time of the baking of the baking step is preferably 1 minute to 60 minutes, more preferably 10 minutes to 60 minutes, and even more preferably 20 minutes to 50 minutes.

The manufacturing method of the embodiment may include a step other than the step described above.

As the other step, a well-known step in a field of photolithography such as a washing step, for example, can be suitably included.

[Decorative Pattern and Touch Panel]

A decorative pattern of the embodiment is a patterned cured material of the photosensitive resin layer including solid contents (that is, components other than the solvent) of the photosensitive resin composition of the embodiment, or a patterned cured material of the photosensitive resin layer of the transfer film of the embodiment.

A touch panel of the embodiment includes the decorative pattern of the embodiment.

The decorative pattern can be manufactured by the manufacturing method of the embodiment, for example.

FIG. 2 is a schematic plan view showing a touch panel 18 including a decorative pattern 20, as an example of the touch panel of the embodiment.

In FIG. 2, since the touch panel 18 includes the decorative pattern 20 having a shape shown in FIG. 2, wirings disposed on a main body of the touch panel 18 can be concealed.

The touch panel of the embodiment is not particularly limited and can be suitably selected according to the purpose.

In the embodiment, the concept of the touch panel includes a so-called touch sensor and a touch pad.

A method of providing a touch panel sensor electrode portion in the touch panel may have any of a bonding type of bonding two transparent electrodes, a type of including transparent electrodes on both surfaces of one substrate, a single surface jumper or a through-hole type, or a single surface lamination type.

Examples of the touch panel include a surface type electrostatic capacitance type touch panel, a projection type electrostatic capacitance type touch panel, and a resistive film type touch panel.

The operation type of the projection type electrostatic capacitance type touch panel is preferably alternating current (AC) driving type rather than direct current (DC) driving type.

The operation type thereof is more preferably a driving method having a short period of time for applying a voltage to an electrode.

The resistive film type touch panel has a basic configuration in which conductive films on a pair of upper and lower substrates each including the conductive film are disposed at the opposing positions through a spacer.

The configuration of the resistive film type touch panel is well known and a well-known technology can be applied without any limitation in the embodiment.

As the type of the electrostatic capacitance type touch panel, a surface type electrostatic capacitance type or a projection type electrostatic capacitance type is used.

The projection type electrostatic capacitance type touch panel has a basic configuration in which an X axis electrode (hereinafter, also referred to as an X electrode) and a Y axis electrode (hereinafter, also referred to as a Y electrode) orthogonal to the X electrode are disposed through an insulator. Examples of the more specific aspect include an aspect in which the X electrode and the Y electrode are formed on separate surfaces on one substrate, an aspect in which the X electrode, an insulator layer, the Y electrode are formed on one substrate in this order, and an aspect in which the X electrode is formed on one substrate and the Y electrode is formed on the other substrate (in this aspect, the bonding configuration of the two substrates is the basic configuration described above).

The configuration of the electrostatic capacitance type touch panel is well known and a well-known technology can be applied without any limitation in the embodiment.

### EXAMPLES

Hereinafter, examples of the embodiment will be described, but the embodiment is not limited to the following examples.

Hereinafter, “part” and “%” respectively mean “parts by mass” and “% by mass”.

<Preparation of Binder>

Binders (polymers 1 to 12) shown in Table 1 were prepared.

Here, the polymers 1 to 7 are the specific binders (that is, binder having an I/O value equal to or greater than 0.5 and a weight-average molecular weight (Mw) equal to or smaller than 25,000), and the polymers 8 to 12 are comparative binders.

TABLE 1

| Polymer 1 | Mw 5,000 | I/O = 0.55 | Acid value | BzMA/MAA = |
|---|---|---|---|---|
| | | | 112 | 70/30 |
| Polymer 2 | Mw 13,500 | I/O = 0.55 | Acid value | BzMA/MAA = |
| | | | 112 | 70/30 |
| Polymer 3 | Mw 13,500 | I/O = 0.55 | Acid value | BzMA/MAA = |
| | | | 80 | 80/20 |
| Polymer 4 | Mw 13,500 | I/O = 0.55 | Acid value | BzMA/MAA = |
| | | | 60 | 88/12 |
| Polymer 5 | Mw 24,000 | I/O = 0.57 | Acid value | MAA/GMA/BzMA = |
| | | | 78 | 23/10/67 |
| Polymer 6 | Mw 20,400 | I/O = 0.88 | Acid value | CHMA/MAA/MMA/GMA = |
| | | | 151 | 38/40/2/20 |
| Polymer 7 | Mw 23,900 | I/O = 0.75 | Acid value | CHMA/MAA/MMA = |
| | | | 192 | 52/46/2 |
| Polymer 8 | Mw 30,000 | I/O = 0.2 | Acid value | St/MAA = |
| | | | 112 | 80/20 |
| Polymer 9 | Mw 30,000 | I/O = 0.6 | Acid value | St/GMA/MAA = |
| | | | 112 | 59/20/21 |
| Polymer 10 | Mw 15,000 | I/O = 0.2 | Acid value | St/MAA = |
| | | | 112 | 80/20 |
| Polymer 11 | Mw 22,600 | I/O = 0.42 | Acid value | St/GMA/MAA = |
| | | | 127 | 67/10/23 |
| Polymer 12 | Mw 5,000 | I/O = 0.41 | Acid value | St/MAA = |
| | | | 188 | 67/33 |

Explanation of Table 1
Mw is a weight-average molecular weight.
I/O is an I/O value.
The unit of acid value is mg/KOH.
The copolymerization ratio is a molar ratio.
BzMA is benzyl methacrylate.
MAA is methacrylic acid.
MMA is methyl methacrylate.
GMA is glycidyl methacrylate.
CHMA is cyclohexyl methacrylate.
St is styrene.

<Preparation of Black Pigment Dispersion Liquid>

A black pigment dispersion liquid including the following list of composition, in which a total amount of solid contents is 34.0% by mass, a content of carbon black (hereinafter, also referred to as “CB”) (black pigment) is 25% by mass, and a content of a dispersion binder (that is, binder as a dispersing agent) is 9.0% by mass, was prepared.

˜List of Black Pigment Dispersion Liquid˜
Carbon black (black pigment): 25.0% by mass
Dispersion binder (that I, binder as a dispersing agent): 9.0% by mass
Propylene glycol monomethyl ether acetate: 66.0% by mass

As the dispersion binder, a random copolymer of benzyl methacrylate/methacrylic acid [molar ratio (benzyl methacrylate/methacrylic acid=72/28, weight-average molecular weight of 37,000) was used.

### Example 1

<Producing of Photosensitive Resin Composition>

By sufficiently stirring and mixing components in the following list, a photosensitive resin composition was produced.

˜List of Photosensitive Resin Composition˜
Black pigment dispersion liquid: 161 parts

—Polymerizable Monomer—
A-NOD-N: 3.6 parts

(Shin-Nakamura Chemical Co., Ltd., difunctional monomer, molecular weight of 226)
A-DCP: 10.8 parts

(Shin-Nakamura Chemical Co., Ltd., difunctional monomer, molecular weight of 304)
8UX-015A: 7.2 parts

(Taisei Fine Chemical Co., Ltd., 15-functional monomer, molecular weight of 2,078)
A-DPH: 2.4 parts

(Shin-Nakamura Chemical Co., Ltd., hexafunctional monomer, molecular weight of 578)

Binder
Polymer 1: 52.6 parts

—Polymerization Initiator—
OXE-02: 4.1 parts (3.0% by mass with respect to a total amount of solid contents in photosensitive resin composition)

(BASF Japan Ltd., IRGACURE (registered trademark) OXE 02, ethanone, 1-[9-ethyl-6-(2-methylbenzoyl)-9H-carbazol-3-yl]-, 1-(0-acetyloxime))

—Solvent—
MMPG-Ac: 353 parts

(propylene glycol monomethyl ether acetate)
MEK: 404 parts

(methyl ethyl ketone)

—Surfactant—
F-784-F: 1.00 parts

(DIC Corporation, MEGAFACE (registered trademark) F-784-F)

<Manufacturing of Transfer Film>

A coating solution for a thermoplastic resin layer formed of the following list H1 was applied and dried on a temporary support which is a polyethylene terephthalate film having a thickness of 75 μm using a slit-shaped nozzle to form a thermoplastic resin layer having a film thickness after drying of 15.1 μm.

Next, a coating solution for an oxygen insulating layer formed of the following list P1 was applied on the thermoplastic resin layer and dried to form an oxygen insulating layer having a film thickness after drying of 1.6 μm.

Then, the photosensitive resin composition was applied onto the oxygen insulating layer and dried, to form a photosensitive resin layer having a film thickness after drying of 2.0 μm.

Then, a protective film (polypropylene film having a thickness of 12 μm) was pressure-bonded onto the photosensitive resin layer.

By doing so, a transfer film having a laminated structure of protective film/photosensitive resin layer/oxygen insulating layer/thermoplastic resin layer/temporary support was obtained.

˜Coating Solution for Thermoplastic Resin Layer: List H1˜
Methanol: 11.1 parts
Propylene glycol monomethyl ether acetate: 6.36 parts
Methyl ethyl ketone: 52.4 parts
Copolymer of methyl methacrylate/2-ethylhexyl acrylate/benzyl methacrylate/methacrylic acid: 5.83 parts

(Copolymerization composition ratio (molar ratio)=55/11.7/4.5/28.8, weight-average molecular weight=100,000, Tg≈70° C.)
Copolymer of styrene/acrylic acid: 13.6 parts

(Copolymerization composition ratio (molar ratio)=63/37, weight-average molecular weight=10,000, Tg≈100° C.)
2,2-bis [4-(methacryloxypolyethoxy) phenyl] propane: 9.1 parts

(Shin-Nakamura Chemical Co., Ltd.)
Fluorine-based surfactant: 0.54 parts

(Methyl ethyl ketone solution having the amount of solid contents of 30% by mass, DIC Corporation, MEGAFACE (registered trademark) F780F)

˜Coating Solution for Oxygen Insulating Layer: List P1˜
PVA205: 32.2 parts

(polyvinyl alcohol, manufactured by Kuraray Co., Ltd., saponification degree=88%, polymerization degree of 550)
Polyvinyl pyrrolidone: 14.9 parts

(ISP Japan, K-30)
Distilled water: 524 parts
Methanol: 429 parts

<Evaluation>

The following evaluation was performed using the transfer film.

The results are shown in Table 2.

(Developability)

By performing the evaluations of the period of the development time and the development residue below, the developability of the photosensitive resin layer transferred from the transfer film by the developer which is a carbonate aqueous solution was evaluated.

Among the evaluation results of the period of the development time and the development residue below, a case where at least one of the evaluation results is “D” means that developability by the developer which is a carbonate aqueous solution is poor.

—Period of the Development Time—

By performing the evaluation of the period of the development time, it is evaluated whether or not the photosensitive resin layer can be developed by the carbonate aqueous solution.

First, the protective film was peeled off from the transfer film, the transfer film, from which the protective film is peeled, and the base material (colorless polyester film having a thickness of 200 μm) were overlapped so that the photosensitive resin layer of the transfer film and the base material are in contact with each other, and a laminated sample having a laminated structure of temporary support/thermoplastic resin layer/oxygen insulating layer/photosensitive resin layer/base material was obtained.

Next, the temporary support was peeled off from the laminated sample, and after the peeling, a shower development was performed using a sodium carbonate aqueous solution (pH of 10.0 to 11.0 at 25° C.; the same applies hereinafter) having a concentration of 1% by mass at 30° C. as the developer, and accordingly, the thermoplastic resin layer, the oxygen insulating layer, and the photosensitive resin layer were dissolved. In this case, the time when the dissolving of the photosensitive resin layer is completed was visually confirmed, and this time was recorded as a period of development time.

The period of development time was evaluated according to the following evaluation standard based on the obtained period of development time.

In the following evaluation standard, A to C are practically acceptable.

—Evaluation Standard of Period of Development Time—

A: Period of development time was shorter than 30 seconds and development could be performed.

B: Period of development time was equal to or longer than 30 seconds and shorter than 40 seconds and development could be performed.

C: Period of development time was equal to or longer than 40 seconds and shorter than 45 seconds and development could be performed.

D: Even in a case where the development was performed for 45 seconds, the photosensitive resin layer remains, and the development of the photosensitive resin layer could not be performed.

—Development Residue—

By evaluating the development residue, it was evaluated whether or not the development residue can be prevented, in a case of developing the photosensitive resin layer by the carbonate aqueous solution.

First, in the same manner as in the evaluation of the period of development time, a laminated sample having a laminated structure of temporary support/thermoplastic resin layer/oxygen insulating layer/photosensitive resin layer/base material was prepared.

Next, the pattern mask was disposed on the temporary support of the laminated sample (side opposite to the thermoplastic resin layer in a view of the temporary support), and the photosensitive resin layer of the laminated sample was exposed by a metal halide lamp from the above the pattern mask. As the pattern mask, a pattern mask for forming a fine line pattern of lines and spaces was used.

Then, the temporary support was peeled off from the laminated sample, and after the peeling, shower development was performed for 45 seconds using a sodium carbonate aqueous solution having a concentration of 1% by mass at 30° C. as the developer, and accordingly, the thermoplastic resin layer, the oxygen insulating layer, and the photosensitive resin layer of the unexposed portion were dissolved, and the fine line pattern was obtained.

After the development, the outer portion (unexposed portion) of the fine line pattern was visually observed, and the development residue of the photosensitive resin layer was evaluated based on the following evaluation standard.

In the following evaluation standard, A to C are practically acceptable.

—Evaluation Standard of Development Residue—

A: No development residue is observed.

B: no occurrence of development residue is observed on the periphery and outer side of the fine line pattern, and development residue can be only observed on the edge portion of the base material.

C: slight development residue can be observed on the periphery of the fine line pattern.

D: the dissolving of the photosensitive resin layer of the unexposed portion is not completed and the fine line pattern is not obtained.

(Pattern Fragments)

First, the fine line pattern was formed in the same manner as in the formation of the fine line pattern in the evaluation of the development residue, and the obtained fine line pattern was baked (heated) at 145° C. for 30 minutes with an oven.

Next, the baked fine line pattern was observed with an optical microscope, and the presence or absence of the pattern fragments was evaluated based on the following evaluation standard.

—Evaluation Standard of Pattern Fragments—

A: No pattern fragments of the fine line pattern was observed.

B: Slight pattern fragments of the fine line pattern were observed, but it is in the practically acceptable range.

C: pattern fragments of the fine line pattern were observed, and it is beyond the practically acceptable range.

(Taper Angle (Cross Section Shape of Pattern))

The cross section shape of the fine line pattern baked in the evaluation of the pattern fragments was observed with a scanning electron microscope (SEM), and an SEM image was obtained.

The taper angle of the fine line pattern was measured using the obtained SEM image, and the taper angle of the fine line pattern (cross section shape of pattern) was evaluated based on the evaluation standard.

FIG. 3 is a schematic cross sectional view of a fine line pattern and a base material of the example and a schematic cross sectional view for describing a taper angle of a cross section of the fine line pattern.

As shown in FIG. 3, in the example, an angle formed by a lower surface of a fine line pattern 21 (contact surface with a base material 22) and a side surface of the fine line pattern 21 was set as a taper angle θ° of the fine line pattern 21.

—Evaluation Standard of Taper Angle—

A: Taper angle of the fine line pattern was 60° to 90° and the cross section shape of the fine line pattern was excellent.

B: Taper angle of the fine line pattern was 30° to 60° and the cross section shape of the fine line pattern was in the practically acceptable range.

C: Taper angle of the fine line pattern was smaller than 30° and the cross section shape of the fine line pattern was beyond the practically acceptable range.

D: Taper angle of the fine line pattern was greater than 90° and the cross section shape of the fine line pattern was beyond the practically acceptable range.

### Examples 2 to 12 and Comparative Examples 1 to 5

The same operations were performed in the same manner as in Example 1, except that the components of the photosensitive resin composition in Example 1 were changed as shown in Table 2 and Table 3.

The results are shown in Table 2 and Table 3.

TABLE 2

| | | | Example | Example | Example | Example | Example | Example | Example | Example | Example | Example | Example | Example |
|---|---|---|---|---|---|---|---|---|---|---|---|---|---|---|
| | | | 1 | 2 | 3 | 4 | 5 | 6 | 7 | 8 | 9 | 10 | 11 | 12 |
| Black pigment dispersion liquid | | | 161 | 161 | 161 | 161 | 161 | 161 | 161 | 161 | 161 | 161 | 161 | 161 |
| (CB + dispersion binder + MMPG-Ac) | | | | | | | | | | | | | | |
| Polymerizable | A-NOD-N | Shin-Nakamura | 3.6 | 3.6 | 3.6 | 3.6 | 3.6 | 3.6 | 3.6 | 3.6 | 3.2 | 3.9 | 2.4 | 3.6 |
| monomer | | Chemical Co., Ltd., | | | | | | | | | | | | |
| | | difunctional monomer | | | | | | | | | | | | |
| | A-DCP | Shin-Nakamura | 10.8 | 10.8 | 10.8 | 10.8 | 10.8 | 10.8 | 10.8 | 10.8 | 9.5 | 11.7 | 9.6 | 10.8 |
| | | Chemical Co., Ltd., | | | | | | | | | | | | |
| | | difunctional monomer | | | | | | | | | | | | |
| | 8UX-015A | Taisei Fine | 7.2 | 7.2 | 7.2 | 7.2 | 7.2 | 7.2 | 7.2 | 7.2 | 6.3 | 7.8 | 10.8 | |
| | | Chemical Co., Ltd., | | | | | | | | | | | | |
| | | 15-functional monomer | | | | | | | | | | | | |
| | A-DPH | Shin-Nakamura | 2.4 | 2.4 | 2.4 | 2.4 | 2.4 | 2.4 | 2.4 | 2.4 | 2.1 | 2.6 | 1.2 | 2.4 |
| | | Chemical Co., Ltd., | | | | | | | | | | | | |
| | | difunctional monomer | | | | | | | | | | | | |
| | DPHA | hexafunctional | | | | | | | | | | | | 7.20 |
| | | monomer | | | | | | | | | | | | |
| Specific binder | Polymer 1 | Mw5000 I/O = 0.55 | 52.6 | | | | | | | | | | | |
| | | Acid value 112 | | | | | | | | | | | | |
| | Polymer 2 | Mw13500 I/O = 0.55 | | 52.6 | | | | | | 52.6 | 55.6 | 50.6 | 52.6 | 52.6 |
| | | Acid value 112 | | | | | | | | | | | | |
| | Polymer 3 | Mw13500 I/O = 0.55 | | | 52.6 | | | | | | | | | |
| | | Acid value 80 | | | | | | | | | | | | |
| | Polymer 4 | Mw13500 I/O = 0.55 | | | | 52.6 | | | | | | | | |
| | | Acid value 60 | | | | | | | | | | | | |
| | Polymer 5 | Mw24000 I/O = 0.57 | | | | | 52.6 | | | | | | | |
| | | Acid value 78 | | | | | | | | | | | | |
| | Polymer 6 | Mw20400 I/O = 0.88 | | | | | | 52.6 | | | | | | |
| | | Acid value 151 | | | | | | | | | | | | |
| | Polymer 7 | Mw23900 I/O = 0.75 | | | | | | | 52.6 | | | | | |
| | | Acid value 192 | | | | | | | | | | | | |
| Comparative | Polymer 8 | Mw30000 I/O = 0.2 | | | | | | | | | | | | |
| binder | | Acid value 112 | | | | | | | | | | | | |
| | Polymer 9 | Mw30000 I/O = O.6 | | | | | | | | | | | | |
| | | Acid value 112 | | | | | | | | | | | | |
| | Polymer 10 | Mw15000 I/O = 0.2 | | | | | | | | | | | | |
| | | Acid value 112 | | | | | | | | | | | | |
| | Polymer 11 | Mw22600 I/O = 0.42 | | | | | | | | | | | | |
| | | Acid value 127 | | | | | | | | | | | | |
| | Polymer 12 | Mw5000 I/O = 0.41 | | | | | | | | | | | | |
| | | Acid value 188 | | | | | | | | | | | | |
| Polymerization | 0XE-02 | | 4.1 | 4.1 | 4.1 | 4.1 | 4.1 | 4.1 | 4.1 | 5.3 | 4.1 | 4.1 | 4.1 | 4.1 |
| initiator | | | | | | | | | | | | | | |
| Solvent | MMPG-Ac | | 353 | 353 | 353 | 353 | 353 | 353 | 353 | 353 | 354 | 354 | 354 | 354 |
| | MEK | | 404 | 404 | 404 | 404 | 404 | 404 | 404 | 404 | 404 | 404 | 404 | 404 |
| Surfactant | F-784-F | | 1.00 | 1.00 | 1.00 | 1.00 | 1.00 | 1.00 | 1.00 | 0.26 | 0.26 | 0.26 | 0.26 | 0.26 |
| M/B ratio | | | 0.36 | 0.36 | 0.36 | 0.36 | 0.36 | 0.36 | 0.36 | 0.36 | 0.30 | 0.40 | 0.36 | 0.36 |
| Total amount of solid contents | | | 136.4 | 136.4 | 136.4 | 136.4 | 136.4 | 136.4 | 136.4 | 136.9 | 135.7 | 135.7 | 135.8 | 135.7 |
| Content of pigment with respect to total | | | 29.5 | 29.5 | 29.5 | 29.5 | 29.5 | 29.5 | 29.5 | 29.4 | 29.6 | 29.6 | 29.6 | 29.6 |
| amount of solid contents (% by mass) | | | | | | | | | | | | | | |
| Content of polymerization initiator with respect to | | | 3.0 | 3.0 | 3.0 | 3.0 | 3.0 | 3.0 | 3.0 | 3.9 | 3.0 | 3.0 | 3.0 | 3.0 |
| total amount of solid contents (% by mass) | | | | | | | | | | | | | | |
| Content of difunctional monomer with respect to | | | 70 | 70 | 70 | 70 | 70 | 70 | 70 | 70 | 70 | 70 | 55 | 70 |
| total amount of polymerizable monomer (% by mass) | | | | | | | | | | | | | | |
| Evaluation | Developability | Period of | A | B | B | C | C | A | A | B | C | A | C | B |
| result | | development time | | | | | | | | | | | | |
| | | Development residue | B | B | B | B | B | A | A | B | B | B | C | C |

| | | | | | | | | | | | | |
|---|---|---|---|---|---|---|---|---|---|---|---|---|
| Pattern fragments | B | B | A | A | A | B | B | A | A | B | B | B |
| Taper angle | B | A | A | A | A | A | A | A | B | A | B | A |
| (cross section shape of pattern) | | | | | | | | | | | | |

TABLE 3

| | | | Comparative | Comparative | Comparative | Comparative | Comparative |
|---|---|---|---|---|---|---|---|
| | | | Example | Example | Example | Example | Example |
| | | | 1 | 2 | 3 | 4 | 5 |
| Black pigment dispersion liquid | | | 161 | 161 | 161 | 161 | 161 |
| (CB + dispersion binder + MMPG-Ac) | | | | | | | |
| Polymerizable | A-NOD-N | Shin-Nakamura | 3.6 | 3.6 | 3.6 | 3.6 | 3.6 |
| monomer | | Chemical Co., Ltd., | | | | | |
| | | difunctional monomer | | | | | |
| | A-DCP | Shin-Nakamura | 10.8 | 10.8 | 10.8 | 10.8 | 10.8 |
| | | Chemical Co., Ltd., | | | | | |
| | | difunctional monomer | | | | | |
| | 8UX-015A | Taisei Fine | 7.2 | 7.2 | 7.2 | 7.2 | 7.2 |
| | | Chemical Co., Ltd., | | | | | |
| | | 15-functional monomer | | | | | |
| | A-DPH | Shin-Nakamura | 2.4 | 2.4 | 2.4 | 2.4 | 2.4 |
| | | Chemical Co., Ltd., | | | | | |
| | | difunctional monomer | | | | | |
| | DPHA | hexafunctional | | | | | |
| | | monomer | | | | | |
| Specific binder | Polymer 1 | Mw5000 I/O = 0.55 | | | | | |
| | | Acid value 112 | | | | | |
| | Polymer 2 | Mw13500 I/O = 0.55 | | | | | |
| | | Acid value 112 | | | | | |
| | Polymer 3 | Mw13500 I/O = 0.55 | | | | | |
| | | Acid value 80 | | | | | |
| | Polymer 4 | Mw13500 I/O = 0.55 | | | | | |
| | | Acid value 60 | | | | | |
| | Polymer 5 | Mw24000 I/O = 0.57 | | | | | |
| | | Acid value 78 | | | | | |
| | Polymer 6 | Mw20400 I/O = 0.88 | | | | | |
| | | Acid value 151 | | | | | |
| | Polymer 7 | Mw23900 I/O = 0.75 | | | | | |
| | | Acid value 192 | | | | | |
| Comparative | Polymer 8 | Mw30000 I/O = 0.2 | 52.6 | | | | |
| binder | | Acid value 112 | | | | | |
| | Polymer 9 | Mw30000 I/O = 0.6 | | 52.6 | | | |
| | | Acid value 112 | | | | | |
| | Polymer 10 | Mw15000 I/O = 0.2 | | | 52.6 | | |
| | | Acid value 112 | | | | | |
| | Polymer 11 | Mw22600 I/O = 0.42 | | | | 52.6 | |
| | | Acid value 127 | | | | | |
| | Polymer 12 | Mw5000 I/O = 0.41 | | | | | 52.6 |
| | | Acid value 188 | | | | | |
| Polymerization | OXE-02 | | 4.1 | 4.1 | 4.1 | 4.1 | 4.1 |
| initiator | | | | | | | |
| Solvent | MMPG-Ac | | 353 | 353 | 353 | 353 | 353 |
| | MEK | | 404 | 404 | 404 | 404 | 404 |
| Surfactant | F-784-F | | 1.00 | 1.00 | 1.00 | 1.00 | 1.00 |
| M/B ratio | | | 0.36 | 0.36 | 0.36 | 0.36 | 0.36 |
| Total amount of solid contents | | | 136.4 | 136.4 | 136.4 | 136.4 | 136.4 |
| Content of pigment with respect to total | | | 29.5 | 29.5 | 29.5 | 29.5 | 29.5 |
| amount of solid contents (% by mass) | | | | | | | |
| Content of polymerization initiator with respect to | | | 3.0 | 3.0 | 3.0 | 3.0 | 3.0 |
| total amount of solid contents (% by mass) | | | | | | | |
| Content of difunctional monomer with respect to | | | 70 | 70 | 70 | 70 | 70 |
| total amount of polymerizable monomer (% by mass) | | | | | | | |
| Evaluation | Developability | Period of | D | C | D | C | C |
| result | | development time | | | | | |
| | | Development residue | D | D | C | D | C |

| | | | | | |
|---|---|---|---|---|---|
| Pattern fragments | — | B | — | B | C |
| Taper angle | — | D | — | C | C |
| (cross section shape of pattern) | | | | | |

—Explanation of Table 2 and Table 3—
Polymers 1 to 12 respectively mean the polymers 1 to 12 shown in Table 1.
The numbers in the column of each component means the amount (parts) of the component.
The blank column means that the component is not included.
The M/B ratio means a ratio of a total content mass of the polymerizable monomer with respect to a total content mass of the binder. For example, the total content mass of the binder in Example 1 is a total content mass of the polymer 1 and the dispersion binder in the black pigment dispersion liquid.
“-” in the column of “pattern fragments” and the column of “taper angle” means that the omission of the evaluation, because the dissolving with the developer which is a carbonate aqueous solution was not performed (that is, development could not be performed).
DPHA means dipentaerythritol hexaacrylate which is a hexafunctional monomer.

As shown in Table 2 and Table 3, in Examples 1 to 12 in which the transfer film including the photosensitive resin layer including the specific binder (that is, binder having an I/O value equal to or greater than 0.5 and a weight-average molecular weight equal to or smaller than 25,000), the polymerizable monomer, and the polymerization initiator was used, the photosensitive resin layer was developed with the developer which is a carbonate aqueous solution and the development residue was prevented. In addition, the baked patterns of Examples 1 to 12 had excellent cross section shapes and the pattern fragments were prevented.

The contents of JP2016-109185A filed on May 31, 2016 are incorporated herein by reference.

All of the documents, the patent applications, and the technology standards described here are incorporated here by reference.

What is claimed is:

1. A photosensitive resin composition comprising:
a binder having an I/O value equal to or greater than 0.5 and a weight-average molecular weight equal to or smaller than 25,000;
a pigment;
a polymerizable monomer; and
a polymerization initiator,
wherein a content of the pigment is equal to or greater than 20% by mass with respect to a total amount of solid contents of the photosensitive resin composition.

2. The photosensitive resin composition according to claim 1, wherein the pigment is a black pigment.

3. The photosensitive resin composition according to claim 1, wherein the polymerizable monomer includes a difunctional monomer.

4. The photosensitive resin composition according to claim 3, wherein a content of the difunctional monomer is equal to or greater than 50% by mass with respect to a total amount of the polymerizable monomer.

5. The photosensitive resin composition according to claim 1, wherein:
the pigment is a black pigment, the polymerizable monomer includes a difunctional monomer; and
a content of the difunctional monomer is equal to or greater than 50% by mass with respect to a total amount of the polymerizable monomer.

6. The photosensitive resin composition according to claim 1, wherein a content of the polymerization initiator is greater than 0% by mass and smaller than 4% by mass with respect to a total amount of solid contents of the photosensitive resin composition.

7. The photosensitive resin composition according to claim 1, wherein a ratio of a total mass content of the polymerizable monomer with respect to a total mass content of the binder is 0.10 to 0.50.

8. The photosensitive resin composition according to claim 1, wherein:
the pigment is a black pigment; and
a ratio of a total mass content of the polymerizable monomer with respect to a total mass content of the binder is 0.10 to 0.50.

9. The photosensitive resin composition according to claim 1, wherein a ratio of a total content mass of the polymerizable monomer with respect to a total content mass of the binder is 0.32 to 0.38.

10. The photosensitive resin composition according to claim 1, wherein an acid value of the binder having an I/O value equal to or greater than 0.5 and a weight-average molecular weight equal to or smaller than 25,000 is equal to or greater than 70 mg/KOH.

11. The photosensitive resin composition according to claim 1, wherein a content of the binder having an I/O value equal to or greater than 0.5 and a weight-average molecular weight equal to or smaller than 25,000 is equal to or greater than 5% by mass with respect to a total amount of solid contents of the photosensitive resin composition.

12. The photosensitive resin composition according to claim 1, wherein a content of the binder having an I/O value equal to or greater than 0.5 and a weight-average molecular weight equal to or smaller than 25,000 is equal to or greater than 50% by mass with respect to a total content of the binder included in the photosensitive resin composition.

13. The photosensitive resin composition according to claim 5, wherein:
a content of the polymerization initiator is greater than 0% by mass and smaller than 4% by mass with respect to a total amount of solid contents of the photosensitive resin composition;
a ratio of a total mass content of the polymerizable monomer with respect to a total mass content of the binder is 0.10 to 0.50;
an acid value of the binder having an I/O value equal to or greater than 0.5 and a weight-average molecular weight equal to or smaller than 25,000 is equal to or greater than 70 mg/KOH;
a content of the binder having an I/O value equal to or greater than 0.5 and a weight-average molecular weight equal to or smaller than 25,000 is equal to or greater than 5% by mass with respect to a total amount of solid contents of the photosensitive resin composition; and
a content of the binder having an I/O value equal to or greater than 0.5 and a weight-average molecular weight equal to or smaller than 25,000 is equal to or greater than 50% by mass with respect to a total content of the binder included in the photosensitive resin composition.

14. The photosensitive resin composition according to claim 1, wherein the binder having an I/O value equal to or greater than 0.5 and a weight-average molecular weight equal to or smaller than 25,000 is a polymer selected from the group consisting of a random copolymer of benzyl (meth)acrylate/(meth)acrylic acid, a random copolymer of styrene/(meth)acrylic acid, a copolymer of cyclohexyl (meth)acrylate/(meth)acrylic acid/methyl (meth)acrylate, a glycidyl (meth)acrylate adduct of a copolymer of cyclohexyl (meth)acrylate/methyl (meth)acrylate/(meth)acrylic acid, a glycidyl (meth)acrylate adduct of a copolymer of benzyl (meth)acrylate/(meth)acrylic acid, a copolymer of allyl (meth)acrylate/(meth)acrylic acid, and a copolymer of benzyl (meth)acrylate/(meth)acrylic acid/hydroxyethyl (meth)acrylate.

15. The photosensitive resin composition according to claim 1, wherein the polymerizable monomer comprises a polymerizable group of ethylenically unsaturated group.

16. The photosensitive resin composition according to claim 1, wherein the polymerizable monomer comprises a urethane (meth)acrylate compound.

17. The photosensitive resin composition according to claim 13, wherein the polymerizable monomer comprises a urethane (meth)acrylate compound.

18. The photosensitive resin composition according to claim 1, which is used for forming a decorative pattern of a touch panel including the decorative pattern.

19. A transfer film comprising:
a temporary support; and
a photosensitive resin layer including solid contents of the photosensitive resin composition according to claim 1.

20. The transfer film according to claim 19, further comprising:
a functional layer disposed between the temporary support and the photosensitive resin layer.

21. The transfer film according to claim 20, which is used for forming a decorative pattern of a touch panel including the decorative pattern.

22. A manufacturing method of a pattern, comprising:
a step of forming a photosensitive resin layer onto a base material using the photosensitive resin composition according to claim 1;
a step of performing pattern exposure of the photosensitive resin layer formed on the base material; and
a step of forming a pattern by developing the pattern-exposed photosensitive resin layer with a developer which is a carbonate aqueous solution.

23. The manufacturing method of a pattern according to claim 22, further comprising:
a step of baking the pattern at a baking temperature equal to or lower than 200° C.

24. A decorative pattern which is a patterned cured material of the photosensitive resin layer including solid contents of the photosensitive resin composition according to claim 1.

25. A touch panel comprising:
the decorative pattern according to claim 24.
